(19) United States
(12) Patent Application Publication
(10) Pub. No.: US 2022/0107380 A1
(43) Pub. Date: Apr. 7, 2022

(54) ELECTRODE AND CELL FOR IN SITU ELECTROCHEMICAL AND ELECTRON PARAMAGNETIC RESONANCE MEASUREMENTS

(71) Applicant: King Abdullah University of Science and Technology, Thuwal (SA)

(72) Inventors: Jeremy Adrian BAU, Thuwal (SA); Abdul-Hamid Mohammad EMWAS, Thuwal (SA)

(21) Appl. No.: 17/604,051

(22) PCT Filed: Mar. 9, 2020
(86) PCT No.: PCT/IB2020/052031

§ 371 Date: Oct. 15, 2021

Related U.S. Application Data
(60) Provisional application No. 62/856,241, filed on Jun. 3, 2019.
(60) Provisional application No. 62/834,634, filed on Apr. 16, 2019.

(51) Int. Cl. G01R 33/60; G01N 24/10; G01N 27/403

(52) U.S. Cl. CPC G01R 33/60; G01N 27/403; G01N 24/10

(57) ABSTRACT

Embodiments of the present disclosure describe an electrochemical-electron paramagnetic resonance (EC-EPR) cell comprising a flat cell member positioned between a top capillary member and a bottom capillary member; a working electrode including a metal wire section configured to be housed within the top capillary member, and a flat metal section attached to the metal wire section; and a reference electrode and counter electrode configured to be housed within the top capillary member; wherein the flat metal section is dimensioned to be inserted, along with a catalyst and electrolyte, into the flat cell member; wherein the flat cell member is configured to orient the flat metal section of the working electrode and catalyst in a region of an electron paramagnetic resonance cavity in which a magnetic component of a microwave field is a maximum.

### BACKGROUND

Electrocatalysis is an increasingly important scientific and technological phenomenon whereby an electric current is applied to connected electrodes submerged in an electrolyte to generate a product. As interest in electrocatalysis has grown over the past several decades, numerous materials and reactions have been reported and studied. In some reactions, especially for homogeneous electrocatalysts, catalysis is carried out by a charge cycle whereby the oxidation state of a component of the electrocatalyst changes with the application of current. Visualizing this in situ change has proven difficult due to the need for electrolyte in electrocatalytic cells; advanced materials characterization techniques typically based on the interaction of the target with various particles often function in vacuum. Electrochemistry itself can be utilized to measure charge states, but often times the presence of more than one element can complicate characteristic behaviors. As novel catalysts continue to be reported, they are often more complicated than previous generations, making direct electrochemical characterization difficult.

EPR is a potent technique that can measure the charge states of atoms with unpaired electrons in the investigated samples. However, EPR has not been utilized often for electrocatalytic studies for several reasons, including: (i) the difficulty of integrating an electrochemical setup with an EPR setup, which also includes the design and preparation of a complicated cell; (ii) the interference of liquids and metals with microwaves that are produced during EPR measurements can limit the collection of spectra; and (iii) the EPR spectra of materials can undergo rapid relaxation to ground state, requiring cryogenic techniques that are generally incompatible with electrochemistry. Studies that feature electrochemical EPR often utilize proxy systems, such as the addition of reducing or oxidizing agents, or brute force-type methods for systems where relaxation is slow, such as carrying out the reaction and then scraping the catalyst from an electrode and then loading in a capillary for measurement. Still, EPR has several important advantages over other characterization techniques for electrocatalysis, namely that it is possible to utilize liquids to carry out measurement, and that it is sensitive even to low concentrations of species with unpaired electrons. Finally, while EPR cannot detect diamagnetic species or ground state bulk metals, these characteristics can be utilized to construct cells that can detect the desired species.

The design of cells for in situ electrochemical electron paramagnetic resonance (EPR) measurements thus has proved challenging. The basic requirements for electrochemical systems are problematic for in situ detection and characterization of species using an EPR spectrometer. Accordingly, it would be desirable to provide an electrochemical-electron paramagnetic resonance cell suitable for in situ detection and/or characterization of electrocatalysts during electrochemistry using electron paramagnetic resonance spectrometers.

### SUMMARY

In general, embodiments of the present disclosure describe electron paramagnetic resonance (EPR) cells, working electrodes for EPR cells, methods of detecting species in-situ, and the like.

Embodiments of the present disclosure describe working electrodes and electrochemical-electron paramagnetic resonance cells that allow for in situ characterization of paramagnetic species generated and/or consumed during electrochemical reactions using an electron paramagnetic resonance spectrometer.

Embodiments of the present disclosure describe an electrochemical-electron paramagnetic resonance (EC-EPR) cell comprising a flat cell member positioned between a top capillary member and a bottom capillary member; a working electrode including a metal wire section configured to be housed within the top capillary member, and a flat metal section attached to the metal wire section; and a reference electrode and counter electrode configured to be housed within the top capillary member; wherein the flat metal section is dimensioned to be inserted, along with a catalyst and electrolyte, into the flat cell member; wherein the flat cell member is configured to orient the flat metal section of the working electrode and catalyst in a region of an electron paramagnetic resonance cavity in which a magnetic component of a microwave field is a maximum.

In some embodiments, the flat metal section is made of a material that does not produce a detectable EPR signal. In some embodiments, the working electrode comprises or consists of one or more materials that do not produce a detectable EPR signal. In some embodiments, the working electrode is a gold wire having an end formed into the flat metal section. In some embodiments, the flat metal section is flat metal foil. In some embodiments, the metal wire section is encapsulated in a polymer. In some embodiments, the polymer-encapsulated metal wire section is further encapsulated by a glass capillary. In some embodiments, the working electrode is a glass rod attached to a flat quartz plate, wherein the glass rod and flat quartz plate are coated with a metal. In some embodiments, the top capillary member is wider than the bottom capillary member. In some embodiments, the EC-EPR cell further comprises one or more ports provided in the top capillary member and/or bottom capillary member. In some embodiments, the EC-EPR cell further comprises one or more sealing members configured to be inserted into the ports of the top capillary member, bottom capillary member, or both the top capillary member and bottom capillary member.

Embodiments of the present disclosure also describe methods of detecting in situ paramagnetic species comprising applying a potential to the EC-EPR cell of the present disclosure.

Embodiments of the present disclosure further describe a working electrode for an in situ electrochemical-electron paramagnetic resonance (EC-EPR) cell comprising a metal wire section attached to a flat metal section, wherein the flat metal section is dimensioned to be inserted, along with a catalyst and electrolyte, into a flat cell member of an EC-EPR cell, wherein the flat cell member of the EC-EPR cell is configured to orient the flat metal section of the working electrode and catalyst in a region of an electron paramagnetic resonance cavity in which a magnetic component of a microwave field is a maximum.

In some embodiments, the working electrode comprises or consists of one or more materials that do not produce a detectable EPR signal. In some embodiments, the working electrode is a gold wire having an end formed into the flat metal section. In some embodiments, the flat metal section is flat metal foil. In some embodiments, the metal wire section is encapsulated in a polymer. In some embodiments, the polymer-encapsulated metal wire section is further encapsulated by a glass capillary. In some embodiments, the working electrode is a glass rod attached to a flat quartz plate, wherein the glass rod and flat quartz plate are coated with a metal.

Embodiments of the present disclosure further describe methods of detecting species using an electron paramagnetic resonance (EPR) spectrometer comprising placing a flat electrochemical-electron paramagnetic resonance (EC-EPR) cell in a resonance cavity of an EPR spectrometer, wherein the flat EPR cell comprises a catalyst deposited on one or more surfaces of a flat metal portion of a working electrode and is configured to orient the catalyst in a region of the resonance cavity in which the magnetic component of a microwave field is a maximum; applying a potential to the electrodes of the EC-EPR cell to initiate a catalyzed electrochemical reaction; and generating an in situ EPR signal from paramagnetic species produced, generated, and/or consumed in the catalyzed electrochemical reaction.

The details of one or more examples are set forth in the description below. Other features, objects, and advantages will be apparent from the description and from the claims.

### BRIEF DESCRIPTION OF DRAWINGS

This written disclosure describes illustrative embodiments that are non-limiting and non-exhaustive. In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

Reference is made to illustrative embodiments that are depicted in the figures, in which:

FIG. 1 is a schematic diagram of an in situ electrochemical-electron paramagnetic resonance (EC-EPR) cell, according to one or more embodiments of the present disclosure.

FIG. 2 is a schematic diagram of a working electrode comprising a flat metal section, according to one or more embodiments of the present disclosure.

FIG. 3 is a schematic diagram of a working electrode comprising a flat quartz plate, according to one or more embodiments of the present disclosure.

FIG. 4 is a flowchart of a method of detecting species using an electron paramagnetic resonance spectrometer, according to one or more embodiments of the present disclosure.

FIG. 5 is am image of an assembled EC-EPR cell, according to one or more embodiments of the present disclosure.

FIG. 6 is an image of an assembled EC-EPR cell placed in a resonance cavity of an EPR spectrometer, according to one or more embodiments of the present disclosure.

FIGS. 7A-7B are EPR spectra showing (A) an EPR spectrum of a gold electrode coated with MoSₓ catalyst in the EPR setup in the absence of an applied electric potential and (B) an EPR spectrum of the gold electrode coated with MoSₓ catalyst with an applied electric potential of −2.5 V versus a reference electrode, resulting in a two part signal, where 2.014 V is the signal for Mo³⁺ and 2.002 V is the signal for organic compounds inside the cell, according to one or more embodiments of the present disclosure.

### DETAILED DESCRIPTION

The present disclosure provides an electrochemical-electron paramagnetic resonance (EC-EPR) cell that overcomes the challenges of integrating an electrochemical system with an EPR cell. The EC-EPR cell permits the in situ characterization of species with unpaired electrons and thus can be used to characterize charged species, such as electrocatalysts, in solid state during electrochemistry. The EC-EPR cell includes, among other things, a flat cell member and a flat metal section (e.g., a thin flat metal section) of a working electrode. A catalyst or electrocatalyst can be deposited on the thin flat metal section of the working electrode and inserted, along with electrolyte, into the flat cell member. Upon being placed in an EPR cavity, the flat cell member is configured to orient the catalyst and electrode in a region of the EPR cavity where the magnetic component of a microwave field is a maximum and the electric component is a minimum. Although conventional cells produce EPR signals that are too weak for detection, the EC-EPR cell of the present disclosure permits the detection of paramagnetic charged species formed in situ during application of a potential.

The EC-EPR cell of the present disclosure advances EPR cell design. The working electrode and flat cell member of the EC-EPR cell are fabricated from, or include, an EPR-invisible material, which is a material that does not produce a detectable EPR signal. The active area of the working electrode can be fashioned into a thin flat metal section, which is sometimes soft, to maximize the surface area of the electrode while minimizing or eliminating interference that would otherwise result from the electrode's absorption and/or transmission of the microwaves. The flat metal section of the working electrode is dimensioned to be inserted, along with a low volume of electrolyte, into the flat cell member. The low volume of electrolyte minimizes the dielectric loss of the EPR cavity and thus improves, or at least maintains, detection sensitivity which is frequently a problem during in situ EPR studies. The reference electrode and counter electrode are positioned outside of the EPR cavity to avoid further interference, and the electrodes are positioned to be available for connecting to a potential. The configuration of the EC-EPR cell permits precise control of potential over the working electrode.

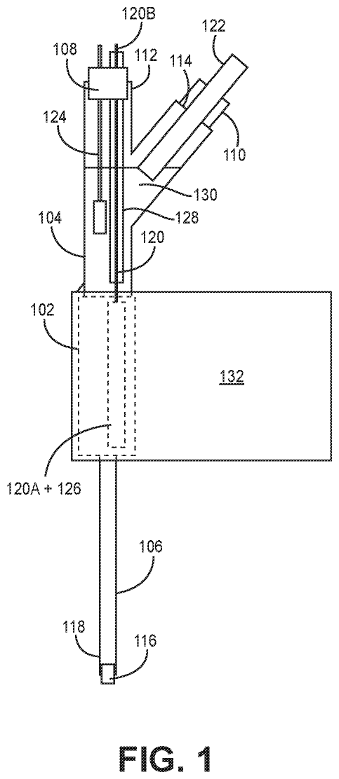

FIG. 1 is a schematic diagram of an in situ electrochemical-electron paramagnetic resonance (EC-EPR) cell, according to one or more embodiments of the present disclosure. The EC-EPR cell 100 comprises a flat cell member 102 adapted to house a working electrode 120 with a catalyst 126 deposited on one or more surfaces and a low volume of electrolyte 130. The flat cell member 102 can be positioned between and in fluid communication with a top capillary member 104 and an optional bottom capillary member 106. The top capillary member 104 can be dimensioned to provide space for at least one electrode, two electrodes, and/or three electrodes. The bottom capillary member 106 can be provided to allow air to exit the flat cell member 102 and top capillary member 104 of the EC-EPR cell 100 during loading with electrolyte 130. The top capillary member 104 and bottom capillary member 106 can each have one or more ports and a sealing member for each of the one or more ports. For example, the top capillary member 104 is sealed using sealing member 108 for port 112 and sealing member 110 for port 114. The bottom capillary member 106 is sealed using sealing member 116 for port 118.

The top capillary member 104, which can be wider than the bottom capillary member 106, houses at least a portion of one or more electrodes. For example, the top capillary member 104 shown in FIG. 1 houses portions of working electrode 120, reference electrode 122, and counter electrode 124. Although a three-electrode system is shown, two-electrode systems can also be employed without departing from the scope of the present disclosure. The sealing members 108 and 110 can be adapted to allow the insertion of the one or more electrodes. For example, in some embodiments, the sealing members 108 and 110 can include rubber septa with holes adapted to receive the working electrode 120, reference electrode 122, and counter electrode 124. Each of the electrodes can also optionally be inserted entirely through sealing members 108 and 110 to be available for connecting to external potentials, such as potentiostats, galvanostats, or other similar devices and/or systems. The sealing members 108 and 110, including the electrodes, can be inserted into the top capillary member 104, forming a gas-tight seal to prevent liquids and/or gases from escaping and/or entering the EC-EPR cell 100.

The working electrode 120 comprises a flat metal section 120A dimensioned to allow it, and optionally a catalyst 126 and electrolyte 130, to be inserted into flat cell member 102. Since the working electrode 120—specifically, the flat metal section 120A—and the flat cell member 102 are the components placed in the EPR cavity 132, the working electrode 120 and flat cell member 102 are preferably constructed from or include EPR-invisible materials or -nearly invisible materials. EPR-invisible or—nearly invisible materials generally refers to materials that do not produce a detectable EPR signal or produce a faintly detectable EPR signal, respectively. An exemplary material for the working electrode 120 is Au, which can be Au wire having an end fashioned under heat and hammering into the flat metal section 120A of the working electrode 120. An exemplary material for the flat cell member 102 is quartz. Other suitable materials include organic materials that do not absorb microwaves and do not have EPR signals, such as Teflon. Other materials can be used for the working electrode 120 and flat cell member 102 without departing from the scope of the present invention. Examples of materials suitable for working electrodes, in general, include Ag, Pt, Pd, Hg, Cu, S, Ni, Os, Ir, Ru, Rh, and C, such as graphite.

The flat metal section 120A generally defines an active area of the working electrode 120. The active area of the working electrode 120 can include the area(s) or surface(s) onto which a catalyst or electrocatalyst 126 is or can be deposited. For example, a catalyst or electrocatalyst 126 can be deposited on one or more surfaces of the flat metal section 120A. The catalyst 126 is preferably confined to the flat metal section 120A or active area of the working electrode 120 and/or not deposited on any portion of the metal wire section 120B of working electrode 120. The catalyst and manner in which it is deposited are not particularly limited. For example, in some embodiments, the catalyst 126 is an electrocatalyst electrodeposited on the flat metal section 120A. Other techniques for depositing the catalyst can be employed without departing from the scope of the present invention.

The flat metal section 120A is attached to metal wire section 120B of the working electrode 120. The metal wire section 120B extends from the flat metal section 120A to sealing member 108. The metal wire section 120B can be inserted through the entire sealing member 108 such that it protrudes from a surface opposing the one into which it was inserted. The protruding portion of the metal wire section 120B can be available for connecting to an external potential. In some embodiments, the surface of the sealing member 108 from which the metal wire section 120B protrudes (e.g., an outside surface) is sealed with epoxy or other similar materials. In some embodiments, the interior portion of the metal wire section 120B (e.g., those placed inside the top capillary member 104) is optionally encapsulated. The encapsulation of the metal wire section 120B can prevent the working electrode 120 from making contact with the counter electrode, reduce contact with electrolyte, and/or to prevent unnecessary signals or resistance losses that might arise from the metal wire section of 120B which is not covered by catalyst 126. For example, the metal wire section 120B can be sheathed or encapsulated in a glass capillary 128, plastics, or combinations thereof. In some embodiments, a bottom portion of the glass capillary is sealed with, for example, Teflon tape. The bottom portion of the glass capillary 128 can be sealed so thermal annealing of the glass is not required, especially if the metal melts at lower temperatures than glass, and/or to prevent volatile solvent from affecting the epoxy on the sealing member 108.

The dimensions of the flat metal section 120A and flat EPR cell 102 are not particularly limited and can be tailored according to a multitude of design considerations, such as the size and shape of the specific EPR cavity and/or EPR spectrometer to be used, among others. In certain embodiments, the flat EPR cell 102 has an internal thickness of about 0.5 mm and the walls of the flat EPR cell 102 comprise about 0.5 mm thick glass. More frequently, but not exclusively, the flat metal section 120A of working electrode 120 is dimensioned to meet the specifications of the EPR spectrometer to be used. In addition, the flat metal section 120A can be dimensioned to minimize the volume of electrolyte 130 present in the flat cell member 102. In some embodiments, the flat metal section 120A has a dimension (e.g., thickness) that is much less than the other dimensions (e.g., length and width) such that the flat metal section 120A is effectively a two-dimensional (2D) active area. For example, in some embodiments, the flat metal section 120A is characterized as a thin flat metal foil or a soft thin flat metal foil. In one embodiment, the flat metal section 120A is a 3 mm by 4 cm flat metal foil electrode with minimal or negligible thickness. The thin flat metal foil can minimize or prevent the absorption and transmission of microwaves by the flat metal section 120A and thus can reduce or eliminate noise and interference with the measurements.

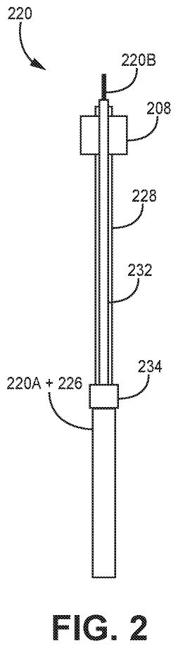

The working electrode 120 can be provided in a variety of configurations. For example, FIG. 2 is a schematic diagram of a working electrode for EC-EPR cells, according to one or more embodiments of the present disclosure. As shown in FIG. 2, the working electrode 220 comprises a flat metal section 220A attached to a metal wire section 220B. The metal wire section 220B extends from the flat metal section 220A and is inserted into and extends through sealing member 208. The flat metal section 220A defines an active area of working electrode 220 where an electrocatalyst 226 is or can be deposited. The metal wire section 220B is encapsulated by a Teflon sheath 232. The metal wire section 220B is further encapsulated by a glass capillary 228, which encloses both the Teflon sheath 230 and the metal wire section 220B. In addition, Teflon tape 234 can be provided around a bottom portion of the glass capillary 228.

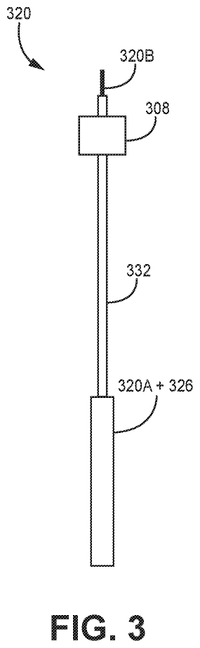

FIG. 3 is a schematic diagram of a working electrode for EC-EPR cells, according to one or more embodiments of the present disclosure. As shown in FIG. 3, the working electrode 320 comprises a flat quartz plate 320A attached to a glass rod 320B. The flat quartz plate 320A is dimensioned to fit within a flat cell member (not shown) and the glass rod 320B is dimensioned to fit within a top capillary member (not shown). For example, in some embodiments, the flat quartz plate 320A is cut to afford an active area that fits within a flat cell member. The glass rod 320B can extend from the flat quartz plate 320A to a sealing member 308 and protrude therefrom similar to other embodiments. The flat quartz plate 320A and/or glass rod 320B can have a metal deposited on the surfaces thereof. For example, in some embodiments, the flat quartz plate 320A and glass rode 320B are sputtered with a metal layer 326 having a thickness of about 50 nm. In some embodiments, a single side of the flat quartz plate is sputtered with a metal layer 326. In some embodiments, two sides of the flat quartz plate is sputtered with a metal layer 326 to form a single continuous electrode surface. The glass rod 320B comprising the metal layer 326 can optionally be encapsulated with a Teflon sheath 332 and/or a glass capillary (not shown).

Referring to FIG. 1, the counter electrode 124 and reference electrode 122 should be dimensioned to fit suitably within the top capillary member 104 or bottom capillary member 106, depending on the configuration. In addition, the counter electrode 124 and reference electrode 122 should be adapted to be inserted into a sealing member, such as sealing members 108 and 110. Otherwise the counter electrode 124 and reference electrode 122 are not particularly limited and thus can be selected from electrodes and electrode materials known in the art. For example, as shown in FIG. 1, in some embodiments, the counter electrode 124 is a wire attached to a mesh.

The assembly of the EC-EPR cell 100 can proceed by depositing a catalyst 126 on the flat metal section 120A via, for example, electrodeposition. The working electrode 120, counter electrode 124, and reference electrode 122 can be inserted into their respective holes formed in the one or more sealing members. For example, in some embodiments, the EC-EPR cell 100 can be assembled by inserting the working electrode 120 and counter electrode 124 into the sealing member 108. The reference electrode 122 can be inserted into the sealing member 110.

Prior to filling the EC-EPR cell 100 with electrolyte 130, the sealing member 116 corresponding to the bottom capillary member 106 can be inserted in the bottom capillary member 106. For example, the sealing member 116 can be inserted into port 118 of the bottom capillary member 106. Upon inserting the sealing member, the electrolyte 130 can be added to the EC-EPR cell 100 through one or more ports of the top capillary member. The electrolyte 130 can include any solvent combined with any organic electrolyte 130. In some embodiments, the electrolyte 130 is preferably a low dielectric solvent combined with any organic electrolyte, such as tetrahydrofuran and 2.0 M tetrabutylammonium hexafluorophosphate. The electrolyte 130 can be added through one or both of ports 112 and 114. During filling with electrolyte 130, air can exit the flat cell member 102 and/or top capillary member 104 and enter the bottom capillary member 106 such that the flat cell member 102 is completely filled with electrolyte 130. In addition, the volume of electrolyte 130 should be sufficient so that electrolyte is in contact with at least a portion of counter electrode 124 and reference electrode 122 once the EC-EPR cell is placed in a resonance cavity 132 of an EPR spectrometer.

Upon filling the EC-EPR cell 100 with electrolyte 130, the sealing member 108, with the working electrode 120 and counter electrode 124 inserted therein, can be inserted into the top capillary member 104 to form a seal with port 112. The inserting of the sealing member 108 into the top capillary ember 104 also positions the flat metal section 120A and catalyst 126 inside the flat cell member 102. The flat cell member 102 thus will include the flat metal section 120A, catalyst 126, and electrolyte 130. Preferably, the flat cell member 102 includes a low volume of electrolyte 130 to minimize dielectric loss, ohmic loss, and/or interference with EPR measurements. The sealing member 110 with the reference electrode 122 inserted therein can be inserted into the top capillary member 104 to form a seal with port 114.

All or a portion of the assembly of the EC-EPR cell 100 can optionally proceed in a clean environment, such as an argon glovebox. For example, in some embodiments, the electrodes are inserted into their respective sealing members outside of a clean environment and then the sealing members with electrodes inserted therein, flat cell member coupled to the top capillary member 104 and bottom capillary member 106 without electrolyte 130, and electrolyte 130 are placed in a clean environment to complete the assembly of the EC-EPR cell 100. In some embodiments, the assembly of the EC-EPR cell 100 does not proceed in a clean environment.

Once assembled, the EC-EPR cell 100 can be placed in the resonance cavity 132 of an EPR spectrometer. The flat EPR cell 102 and/or EC-EPR cell 100 is configured to orient the flat metal section 120 of the working electrode 120, including the catalyst 126, in a region of the resonance cavity in which the magnetic component of a microwave field is a maximum. In many instances, the region in which the working electrode 120 and catalyst 126 is oriented is also where the electric component of the microwave field is a minimum. The portions of the electrodes protruding from the sealing members can be connected to an external potential. For example, in some embodiments, the working electrode, counter electrode, and reference electrode are connected to their respective terminals of a potentiostat. Although a potentiostat can be used as the external potential, other devices and/or systems can be used, such as a galvanostat, among others. Potential then can be applied and in situ EPR measurements can be obtained.

In certain embodiments, a simple EPR cell constructed from quartz, which is EPR-invisible) with substrate is described. The glass cell is constructed from about 0.5 mm thick glass fashioned into a flat cell member that fits into the EPR cavity. The bottom of the flat cell member is attached to a narrow glass capillary to allow air to exit the cell during loading with electrolyte; the top of the cell is connected to a wide capillary (about 1 cm diameter) so that a wide foil can be inserted into the flat cell member. All capillaries are capped with a gas-tight septa to prevent water from entering the cell. The top capillary may have multiple outlets each with their own septa to facilitate loading. Holes are present in the rubber septa to allow the insertion of a reference electrode, counter electrode (a wire attached to a mesh), and working electrode. The working electrode can be any thin metal that is EPR-silent. For example, a gold wire having an end that has been fashioned into a rectangular, flat foil can be used. Catalyst is deposited onto the flat foil (i.e. by electrodeposition) and the wire is then sealed and sheathed in a glass capillary inserted through the rubber septum on the top of the cell that is sealed on the outside top end with epoxy. Teflon tape may be used to help seal the capillary, so that thermal annealing of the glass is not required especially if the metal melts at lower temperatures than glass (i.e., gold). Teflon tape sealing on the bottom of the glass capillary also helps prevent volatile solvent from affecting the epoxy at the top of the capillary. Encapsulation of the wire part of the working electrode is helpful to prevent contact with the counter electrode, and also to prevent unnecessary signals that might arise from the wire part of the working electrode which is not covered with catalyst. The counter electrode wire is also inserted through the top septum. The electrolyte can be any solvent, preferably a low dielectric solvent combined with any organic electrolyte, i.e., tetrahydrofuran and 0.2 M tetrabutylammonium hexafluorophosphate. The cell is assembled in a clean environment, i.e. an Argon glovebox, and sealed using rubber septa on both ends. The cell is placed inside the cavity of an EPR spectrometer and a potentiostat is connected to the setup, with the working electrode clip attached to the working electrode and the counter electrode clip attached to the counter electrode. On application of potential, EPR spectra can be measured with this setup. This is an embodiment of a design that allows for the detection of paramagnetic charged species formed in situ during application of potential on a solid surface. Through use of low electrolyte volume, low electrode volume, and EPR-silent materials, in addition to maximizing the surface area of the electrode, it becomes possible to detect otherwise weak signals.

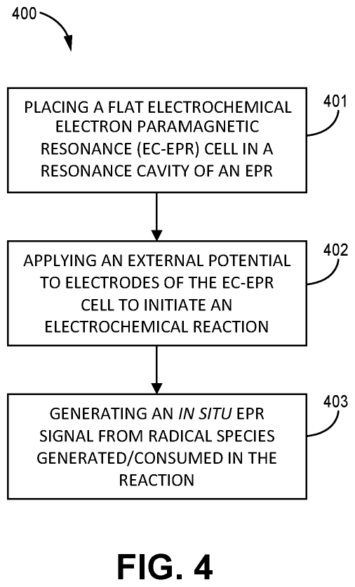

FIG. 4 is a flowchart of a method of detecting species using an electron paramagnetic resonance (EPR) spectrometer, according to one or more embodiments of the present disclosure. The method 400 comprises placing 401 a flat cell member of an electrochemical-electron paramagnetic resonance (EC-EPR) cell in a resonance cavity of an EPR spectrometer. The placing can proceed by positioning, installing, providing, and inserting, among other techniques. Advantageously, the EC-EPR cells of the present disclosure can be used with any EPR spectrometer, including conventional EPR spectrometers. Accordingly, the EPR spectrometers used herein are not particularly limited. The flat cell member can include a catalyst deposited on one or more surfaces of a working electrode, such as a flat metal section of a working electrode. The EC-EPR cell and/or the flat cell member can be configured to orient the catalyst in a region of the resonance cavity in which the magnetic component of a microwave field is a maximum. This region can also be a region in which the electric component of the microwave field is a minimum. A potential can be applied 402 via connections between the electrodes and an external potential. The applying 402 of the potential to the electrodes of the EC-EPR cell can initiate a catalyzed electrochemical reaction. The electrochemical reactions employed herein are not particularly limited and one skilled in the art will readily understand reactions suitable for the present method. The potential can be applied using a potentiostat. Other devices and/or systems can be used to apply a potential, such as a galvanostat, among others. During in situ EPR measurements, an EPR signal is generated 403 from species with unpaired elections, such as radicals. The species can include reactants, reaction intermediates, reaction products, and/or species otherwise produced, generated, or consumed during the electrochemical reaction.

The following Examples describe a technique and cell that allow for in situ characterization of electrocatalysts during electron paramagnetic resonance (EPR) studies. A soft, EPR-invisible foil with the desired electrocatalyst deposited on the surface is attached to a wire and inserted into a flat quartz cell filled with organic electrolyte so that the redox state of the catalyst can be measured with applied potential. In the present invention, we disclose a technique that can be used to characterize charged species in solid state during electrochemistry. To accomplish this technique, we also disclose an overall setup that allows for charged state measurement.

The following Examples are intended to illustrate the above invention and should not be construed as to narrow its scope. One skilled in the art will readily recognize that the Examiners suggest many other ways in which the invention could be practiced. It should be understand that numerous variations and modifications may be made while remaining within the scope of the invention.

### Example 1

### EPR Cell for Bruker EMX EPR Spectrometer

An EC-EPR cell designed for a Bruker EMX EPR spectrometer is described herein. A flat cell made of quartz dimensioned to be about 4 cm long×about 1 cm wide×about 1.5 mm thick, with an internal thickness of about 0.5 mm and cell walls made of about 0.5 mm thick glass. A top capillary member and bottom capillary member were attached to both ends of the flat quartz cell. EC-EPR cell was found to be superior to conventional electrochemical cells, such as a Wilmad-LabGlass electrochemical cell, which has a constriction between the top capillary and flat cell that limits the width of the electrode and thus reduces surface area.

A 0.5 mm gold wire was used for the working electrode. The gold wire was fashioned via heat and hammering into a 3 mm×4 cm flat electrode with minimal thickness i.e., like foil. The rest of the wire (the non-flat region) remained intact. To prepare the top septum, a small glass tube, such as a capillary, was used to puncture a hole in the septum, such that the capillary extended close to the flat cell when inserted into the electrochemical cell. The wire was then inserted from the bottom of the septum so that the flat end of the wire would be within the flat cell when the cell was fully assembled. Teflon tape was wrapped around the wire, from the base of the flattened region towards the capillary. A counter electrode wire was punctured through the septum. A separate septum for a reference electrode was prepared by hollowing out the separate septum with a blade and carving a hole that would form an airtight seal once the reference electrode is inserted. The hole at the bottom of the cell was sealed by a third and final tight fitting septum.

With the working-electrode septum device fully assembled, a catalyst was added to the working electrode via electrodeposition. The working electrode-septum was placed into a glovebox along with the electrochemical cell, the reference electrode septum with reference electrode, the third septum and the electrolyte. In the glovebox, the third septum was used to seal the bottom of the cell. Next, electrolyte was loaded into the cell such that the entire flat cell was full of electrolyte and the liquid would touch the counter electrode once the main working electrode-septum is inserted into the cell. The working electrode/counter electrode/septum were then loaded into one of the top capillary holes. The reference electrode septum, with reference electrode inserted therein, was inserted into the other top capillary hole. The sealed cell was then removed from the glovebox and placed into a Bruker EMX EPR Spectrometer and connected appropriately to a potentiostat using alligator clips, with the gold wire attached to the working electrode line, the reference electrode attached to the working electrode line, and the counter electrode attached to the counter electrode line. Using a computer connected to the potentiostat, potential can be applied. Similarly, EPR measurements can be applied after tuning the spectrometer according to manufacturer instructions.

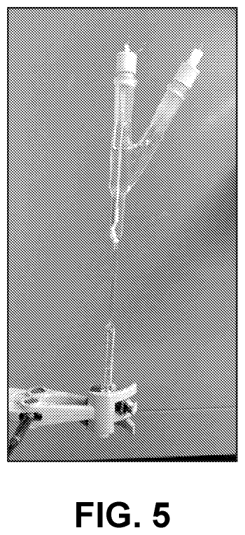

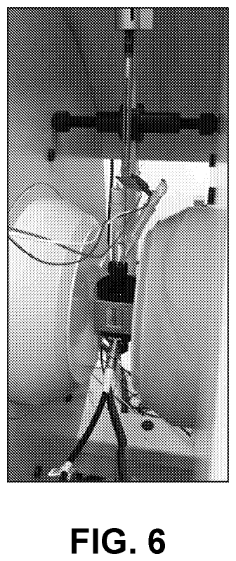

See FIGS. 1-2 for schematic drawings of the EC-EPR cell and working electrode described in the present Example. See also FIGS. 5-6 for images of an assembled EC-EPR cell and the assembled EC-EPR cell placed in a resonance cavity of an EPR spectrometer, according to one or more embodiments of the present disclosure.

### Example 2

### Non-Wire Working Electrode

A non-wire working electrode prepared from a custom-made holder is described. The custom-made holder included a flat quartz plate that could be placed into the cell. The flat quartz plate was attached to a thin glass rod that could fit into the top capillary. The quartz plate was cut into dimensions that would fit into the flat cell. Prior to use, the glass holder was sputtered with 50 nm gold (with an adhesion layer of Cr or Ti) on one, or even both sides (for both sides, the entire flat piece needed to be coated to form a single electrode surface). The glass rod functioned as the wire described in Example 1. The glass rod was inserted through a septa and loaded into the cell and sheathed in Teflon tape. Depending on the thickness of the quartz plate, the cell thickness can be adjusted appropriately, i.e. to have minimal electrolyte volume.

See FIG. 3 for a schematic drawing of a working electrode comprising a flat quartz plate attached to a glass rod.

### Example 3

### Application of Electrical Potential to EC-EPR Cell

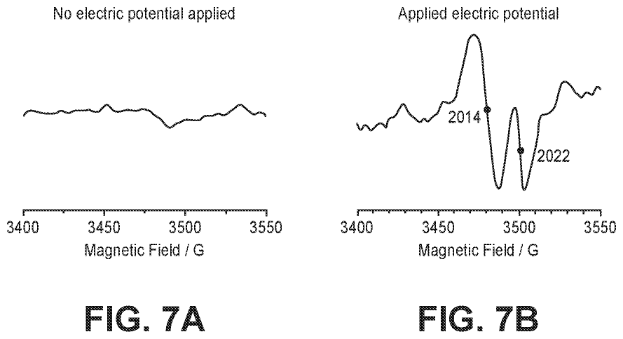

MoSx is a well-known hydrogen evolution catalyst for water splitting. To acquire the useful information, the gold working electrode wire was covered with MoSx using electrodeposition. Next, the wire was placed into the flat part of the glass cell. The cell was loaded with an electrolyte fluid, such as acetonitrile or tetrahydrofuran. A counter electrode was added to the cell, and the entire device was placed within the cavity of an EPR spectrometer. The electrodes were connected to wires from a potentiostat, and the potential or current were manually changed on a computer as needed. The EPR spectrometer was otherwise operated as described by the manufacturer. FIGS. 7A-7B are EPR spectra showing (A) an EPR spectrum of a gold electrode coated with MoSₓ catalyst in the EPR setup in the absence of an applied electric potential and (B) an EPR spectrum of the gold electrode coated with MoSₓ catalyst with an applied electric potential of −2.5 V versus a reference electrode, resulting in a two part signal, where 2.014 V is the signal for Mo³⁺ and 2.002 V is the signal for organic compounds inside the cell, according to one or more embodiments of the present disclosure.

Other embodiments of the present disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form various embodiments. Thus, it is intended that the scope of at least some of the present disclosure should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

The foregoing description of various preferred embodiments of the disclosure have been presented for purposes of illustration and description. It is not intended to be exhaustive or to limit the disclosure to the precise embodiments, and obviously many modifications and variations are possible in light of the above teaching. The example embodiments, as described above, were chosen and described in order to best explain the principles of the disclosure and its practical application to thereby enable others skilled in the art to best utilize the disclosure in various embodiments and with various modifications as are suited to the particular use contemplated. It is intended that the scope of the disclosure be defined by the claims appended hereto

Various examples have been described. These and other examples are within the scope of the following claims.

1. An electrochemical-electron paramagnetic resonance (EC-EPR) cell, comprising:
a flat section positioned between a top capillary member and a bottom capillary member;
a working electrode including a metal wire section configured to be housed within the top capillary member, and a flat metal section attached to the metal wire section; and
a reference electrode and counter electrode configured to be housed within the top capillary member;
wherein the flat metal section is dimensioned to be inserted, along with a catalyst and electrolyte, into the flat cell member;
wherein the flat cell member is configured to orient the flat metal section of the working electrode and catalyst in a region of an electron paramagnetic resonance cavity in which a magnetic component of a microwave field is a maximum.

2. The EC-EPR cell according to claim 1, wherein the flat section is made of a material that does not produce a detectable EPR signal.

3. The EC-EPR cell according to claim 1, wherein the working electrode comprises or consists of one or more materials that do not produce any EPR signal.

4. The EC-EPR cell according to claim 1, wherein the working electrode is a gold wire having an end formed into the flat metal section.

5. The EC-EPR cell according to claim 4, wherein the flat metal section is flat metal foil.

6. The EC-EPR cell according to claim 1, wherein the metal wire section is encapsulated in a polymer.

7. The EC-EPR cell according to claim 6, wherein the polymer-encapsulated metal wire section is further encapsulated by a glass capillary.

8. The EC-EPR cell according to claim 1, wherein the working electrode is a glass rod attached to a flat quartz plate, wherein the glass rod and flat quartz plate are coated with a metal.

9. The EC-EPR cell according to claim 1, wherein the top capillary member is wider than the bottom capillary member.

10. The EC-EPR cell according to claim 9, further comprising one or more ports provided in the top capillary member and/or bottom capillary member.

11. The EC-EPR cell according to claim 10, further comprising one or more sealing members configured to be inserted into the ports of the top capillary member, bottom capillary member, or both the top capillary member and bottom capillary member.

12. A method of detecting in situ paramagnetic species comprising applying a potential to the EC-EPR cell of claim 1.

13. A working electrode for an in situ electrochemical-electron paramagnetic resonance (EC-EPR) cell, comprising:
a metal wire section attached to a flat metal section, wherein the flat metal section is dimensioned to be inserted, along with a catalyst and electrolyte, into a flat section of an EC-EPR cell,
wherein the flat section of the EC-EPR cell is configured to orient the flat metal section of the working electrode and catalyst in a region of an electron paramagnetic resonance cavity in which a magnetic component of a microwave field is a maximum.

14. The working electrode according to claim 13, wherein the working electrode comprises or consists of one or more materials that do not produce a detectable EPR signal.

15. The working electrode according to claim 14, wherein the working electrode is a gold wire having an end formed into the flat metal section.

16. The working electrode according to claim 15, wherein the flat metal section is flat metal foil.

17. The working electrode according to claim 15, wherein the metal wire section is encapsulated in a polymer.

18. The working electrode according to claim 17, wherein the polymer-encapsulated metal wire section is further encapsulated by a glass capillary.

19. The working electrode according to claim 14, wherein the working electrode is a glass rod attached to a flat quartz plate, wherein the glass rod and flat quartz plate are coated with a metal.

20. (canceled)
